(19) United States
(12) Patent Application Publication
(10) Pub. No.: US 2025/0105196 A1
(43) Pub. Date: Mar. 27, 2025

(54) Semiconductor Die Bonding

(71) Applicant: Wolfspeed, Inc., Durham, NC (US)

(72) Inventors: Afshin Dadvand, Durham, NC (US); Daniel Ginn Richter, Raleigh, NC (US); Devarajan Balaraman, Apex, NC (US)

(21) Appl. No.: 18/475,370

(22) Filed: Sep. 27, 2023

(51) Int. Cl. H01L 23/00

(52) U.S. Cl. CPC H01L 24/32; H01L 24/29; H01L 24/83; H01L 2224/29083; H01L 2224/29084; H01L 2224/29111; H01L 2224/29124; H01L 2224/29139; H01L 2224/29144; H01L 2224/29147; H01L 2224/29155; H01L 2224/29157; H01L 2224/29164; H01L 2224/32245; H01L 2224/83439; H01L 2224/83447

(57) ABSTRACT

Die-attach materials for semiconductor device packages are provided. In one example, a semiconductor device package includes a submount. The semiconductor device package includes a semiconductor die comprising a wide bandgap semiconductor. The semiconductor device package includes a die-attach layer between the submount and the semiconductor die. The die-attach layer comprises gold (Au), tin (Sn), and cobalt (Co).

### FIELD

The present disclosure relates generally to semiconductor device packages.

### BACKGROUND

Semiconductor devices, including power semiconductor devices based on wide bandgap semiconductor materials, may be formed on a semiconductor wafer as part of a semiconductor fabrication process. The semiconductor wafer may be diced into many individual pieces, each containing one or more semiconductor devices. Each of these pieces may be a semiconductor die. One or more semiconductor die may need to be attached to other components as part of packaging of the semiconductor device. For instance, a semiconductor die, such as a wide bandgap semiconductor die, may need to be attached to a conductive lead frame for use in a discrete power semiconductor package or a power module. Materials used to attach the semiconductor die to other components may need to provide a thermal, mechanical, and/or electrical connection of the semiconductor die to the other components.

### SUMMARY

Aspects and advantages of embodiments of the present disclosure will be set forth in part in the following description, or may be learned from the description, or may be learned through practice of the embodiments.

One example aspect of the present disclosure is directed to a semiconductor device package. The semiconductor device package includes a submount. The semiconductor device package includes a semiconductor die comprising a wide bandgap semiconductor. The semiconductor device package includes a die-attach layer between the submount and the semiconductor die. The die-attach layer comprises gold (Au), tin (Sn), and cobalt (Co).

Another example aspect of the present disclosure is directed to an attach material for attaching a wide bandgap semiconductor device to a submount. The attach material comprises a eutectic alloy. The eutectic alloy comprises gold (Au), tin (Sn), and cobalt (Co). A concentration of cobalt in the eutectic alloy is in a range of about 0.01% by weight to about 0.5% by weight.

Another example aspect of the present disclosure is directed to a method for fabricating a semiconductor device package. The method includes providing a die-attach material. The die-attach material comprises gold (Au), tin (Sn), and cobalt (Co). A concentration of cobalt (Co) in the die-attach material is in a range of about 0.01% by weight to about 0.5% by weight. The method includes attaching a semiconductor die to a submount with the die-attach material.

These and other features, aspects and advantages of various embodiments will become better understood with reference to the following description and appended claims. The accompanying drawings, which are incorporated in and constitute a part of this specification, illustrate embodiments of the present disclosure and, together with the description, explain the related principles.

### BRIEF DESCRIPTION OF THE DRAWINGS

Detailed discussion of embodiments directed to one of ordinary skill in the art are set forth in the specification, which refers to the appended figures, in which:

FIG. 1 depicts a portion of an example semiconductor device package with a semiconductor die attached to a submount using a die-attach material according to example embodiments of the present disclosure.

FIG. 2 depicts a portion of an example semiconductor device package with a semiconductor die attached to a submount using a die-attach material according to example embodiments of the present disclosure.

FIG. 3 depicts a portion of an example semiconductor device package with a semiconductor die attached to a submount using a die-attach material according to example embodiments of the present disclosure.

FIG. 4 depicts a portion of an example semiconductor device package with a semiconductor die attached to a submount using a die-attach material according to example embodiments of the present disclosure.

FIG. 5 depicts an example semiconductor device package according to example embodiments of the present disclosure.

FIG. 6 depicts an example power module according to example embodiments of the present disclosure.

FIG. 7 depicts an example semiconductor device package according to example embodiments of the present disclosure.

FIG. 8 depicts a flow chart diagram of an example method according to example embodiments of the present disclosure.

FIG. 9 depicts providing an example die-attach material on a semiconductor die according to example embodiments of the present disclosure.

### DETAILED DESCRIPTION

Reference now will be made in detail to embodiments, one or more examples of which are illustrated in the drawings. Each example is provided by way of explanation of the embodiments, not limitation of the present disclosure. In fact, it will be apparent to those skilled in the art that various modifications and variations may be made to the embodiments without departing from the scope or spirit of the present disclosure. For instance, features illustrated or described as part of one embodiment may be used with another embodiment to yield a still further embodiment. Thus, it is intended that aspects of the present disclosure cover such modifications and variations.

Example aspects of the present disclosure are directed to attaching semiconductor die (e.g., wide bandgap semiconductor die) to a submount or other structures in a semiconductor package (e.g., a power module or discrete semiconductor package). In semiconductor packaging, thermal management may be an important aspect of packaging design as it relates to the issue of device degradation at high temperatures. Thermal management is becoming increasingly important as power semiconductor devices have increasingly smaller features that handle higher currents.

Binary eutectic alloys, such as gold-tin (Au—Sn) eutectic alloys, with melting points of about 280° C., have been used for lead (Pb) free die-attach of wide bandgap semiconductor die to submounts (e.g., copper lead frames) in power semiconductor packages. Au—Sn eutectic alloys may possess superior thermal properties compared to, for instance, lead-tin (Pb—Sn) solders. However, excessive formation and growth of intermetallic compounds (IMCs) in Au—Sn eutectic alloy die-attach materials may decrease the quality of the thermal and the mechanical attachment of the semiconductor die to the submount, resulting in decreased operational reliability.

Aspects of the present disclosure relate to a die-attach material that includes a ternary system of a gold-tin-cobalt (Au—Sn—Co). The die-attach material may be a gold-tin-cobalt (Au—Sn—Co) alloy. The alloy may be a eutectic alloy. For instance, in some example embodiments, a semiconductor device package may include a submount (e.g., lead frame, directed bonded copper (DBC) submount, clip, or other connection structure) and one or more semiconductor die. The semiconductor die may include a wide bandgap semiconductor (e.g., silicon carbide, Group III-nitride, etc.). The semiconductor device package may include a die-attach layer between the submount and the semiconductor die. The die-attach layer includes gold (Au), tin (Sn), and cobalt (Co). In some examples, the die-attach layer is a eutectic alloy (e.g., eutectic Au—Sn—Co alloy).

In some examples, a concentration of cobalt in the die-attach layer may be in a range of about 0.01% by weight to about 0.5% by weight, such as in a range of about 0.01% by weight to about 0.25% by weight. In some examples, a concentration of tin (Sn) in the die-attach layer is in a range of about 10% by weight to about 30% by weight. In some examples, a concentration of gold (Au) in the die-attach layer is in a range of about 65% by weight to about 85% by weight. The die-attach layer may be lead (Pb) free.

In some examples, the semiconductor device package may include one or more additional layers, for instance, as part of the backside metallization for the semiconductor die. For instance, the semiconductor device package may include an adhesion layer on or as part of the semiconductor die. The adhesion layer may be, for instance, titanium (Ti). In some embodiments, the semiconductor device package may include a diffusion barrier layer on or as a part of the semiconductor die. The diffusion barrier layer may reduce metal diffusion from the die-attach layer. The diffusion barrier layer may include, for instance, one or more of silver (Ag), nickel (Ni), palladium (Pd), or copper (Cu). In some embodiments, the semiconductor device package may include a protective layer on the die-attach layer. The protective layer may include, for instance, gold (Au).

The ternary Au—Sn—Co die-attach layer according to example embodiments of the present disclosure may be provided (e.g., deposited) on the submount and/or on the semiconductor as a preform, paste, using evaporation (e.g., sputtering), using electrodeposition, and/or other suitable process. In some examples, providing the Au—Sn—Co die-attach layer may include using a bi-layer deposition of a first layer comprising gold and tin (Au—Sn layer) and a second layer comprising gold and cobalt (Au—Co layer). During annealing or bonding of the die-attach layer, the bi-layer structure may result in the ternary Au—Sn—Co die-attach layer according to example embodiments of the present disclosure.

The die-attach layer according to example embodiments of the present disclosure may be provided on the submount and/or on the semiconductor die. The die-attach layer may undergo a bonding process to attach the semiconductor to the submount using the die-attach layer. The bonding process may include an annealing process where the die-attach layer is heated to, for instance, a temperature in a range of about 250° C. to about 380° C., such as about 275° C. to about 350° C.

Other suitable bonding processes may be used without deviating from the scope of the present disclosure. As used herein, the term “bonding” or “bonding process” refers to causing a transition of a material from a first form to a second form. A bonding process may or may not require attaching a component to the material. Sintering, reflow, annealing, heating, curing, exposing to light, and exposing to ultraviolet light are examples of bonding processes and are encompassed by the term “bonding” or “bonding process” in the disclosure and in the claims.

The die-attach layer may be used to attach the semiconductor die to a submount that is a lead frame of a semiconductor package. The lead frame may be a copper lead frame and/or may be a metal-plated lead frame (e.g., silver-plated copper lead frame).

The semiconductor die may include a wide bandgap semiconductor. The wide bandgap semiconductor may be, for instance, silicon carbide. The wide bandgap semiconductor may be, for instance, a Group III-nitride. The semiconductor die may include one or more power semiconductor devices, such as one or more transistor devices, including MOSFETs (metal-oxide semiconductor field-effect transistors), DMOS (double-diffused metal-oxide semiconductor) transistors, HEMTs (high electron mobility transistors), MESFETs (metal-semiconductor field-effect transistors), LDMOS (laterally diffused metal-oxide semiconductor) transistor devices, etc. In some embodiments, the semiconductor die may include one or more diodes (e.g., Schottky diodes). In some embodiments, the semiconductor die may include at least a portion of an amplifier circuit. The semiconductor device package may be a power module. The semiconductor device package may be a discrete power semiconductor device package.

Aspects of the present disclosure provide a number of technical effects and benefits. For instance, the ternary system of Au—Sn—Co may suppress overgrowth of IMCs, improving the mechanical stability of the die-attach during fabrication, reliability testing, and/or operation of the semiconductor device package. Cobalt may quickly react with tin (e.g., below 380° C.). to form three different Co—Sn IMCs, including CoSn₂, Co₃Sn₂ and CoSn. The quick formation of the Co—Sn IMCs may reduce formation of more brittle Au—Sn IMCs, such as dendric ζ′-AusSn and lamellar δ-AuSn in the matrix of the die-attach, as well as growth of Cu₆Sn₅ at the interface with a copper submount (e.g., copper lead frame).

Only a small concentration (e.g., about 0.01 wt. % to about 0.5 wt. %) of cobalt in the die-attach layer may significantly improve the wettability of the die-attach layer by reducing the anisotropy of the surface energy during solidification. The small concentration of cobalt enhances shear and strength properties of the die-attach layer. The small concentration of cobalt reduces the die-attach fatigue especially at elevated temperatures (e.g., 200° C.-350° C.). The cobalt may also segregate to the grain boundaries and thus mitigate electromigration. In contrast, an excessive amount of cobalt may result in a hard and brittle structure that may lower electrical conduction due to the oxidation at the interfaces.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms used herein should be interpreted as having a meaning that is consistent with their meaning in the context of this specification and the relevant art and will not be interpreted in an idealized or overly formal sense unless expressly so defined herein.

It will be understood that when an element such as a layer, structure, region, or substrate is referred to as being “on” or extending “onto” another element, it may be directly on or extend directly onto the other element or intervening elements may also be present and may be only partially on the other element. In contrast, when an element is referred to as being “directly on” or extending “directly onto” another element, there are no intervening elements present, and may be partially directly on the other element. It will also be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present.

As used herein, a first structure “at least partially overlaps” or is “overlapping” a second structure if an axis that is perpendicular to a major surface of the first structure passes through both the first structure and the second structure. A “peripheral portion” of a structure includes regions of a structure that are closer to a perimeter of a surface of the structure relative to a geometric center of the surface of the structure. A “center portion” of the structure includes regions of the structure that are closer to a geometric center of the surface of the structure relative to a perimeter of the surface. “Generally perpendicular” means within 15 degrees of perpendicular. “Generally parallel” means within 15 degrees of parallel.

Relative terms such as “below” or “above” or “upper” or “lower” or “horizontal” or “lateral” or “vertical” may be used herein to describe a relationship of one element, layer or region to another element, layer or region as illustrated in the figures. It will be understood that these terms are intended to encompass different orientations of the device in addition to the orientation depicted in the figures.

Embodiments of the disclosure are described herein with reference to cross-section illustrations that are schematic illustrations of idealized embodiments (and intermediate structures) of the invention. The thickness of layers and regions in the drawings may be exaggerated for clarity. Additionally, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. Similarly, it will be understood that variations in the dimensions are to be expected based on standard deviations in manufacturing procedures. As used herein, “approximately” or “about” includes values within 10% of the nominal value.

Like numbers refer to like elements throughout. Thus, the same or similar numbers may be described with reference to other drawings even if they are neither mentioned nor described in the corresponding drawing. Also, elements that are not denoted by reference numbers may be described with reference to other drawings.

Some embodiments of the invention are described with reference to semiconductor layers and/or regions which are characterized as having a conductivity type such as n type or p type, which refers to the majority carrier concentration in the layer and/or region. Thus, N type material has a majority equilibrium concentration of negatively charged electrons, while P type material has a majority equilibrium concentration of positively charged holes. Some material may be designated with a “+” or “−” (as in N+, N−, P+, P−, N++, N−−, P++, P−−, or the like), to indicate a relatively larger (“+”) or smaller (“−”) concentration of majority carriers compared to another layer or region. However, such notation does not imply the existence of a particular concentration of majority or minority carriers in a layer or region.

Aspects of the present disclosure are discussed with reference to attaching a semiconductor die to a submount that includes a lead frame in a semiconductor package for purposes of illustration and discussion. Those of ordinary skill in the art, using the disclosures provided herein, will understand that the submount may include other structures, such as a DBC submount, a clip (for clip-attach packages), or other structure. The use of the term “submount” is intended to refer to any structure to which the semiconductor die is attached.

In the drawings and specification, there have been disclosed typical embodiments and, although specific terms are employed, they are used in a generic and descriptive sense only and not for purposes of limitation of the scope set forth in the following claims.

With reference now to the Figures, example embodiments of the present disclosure will now be set forth.

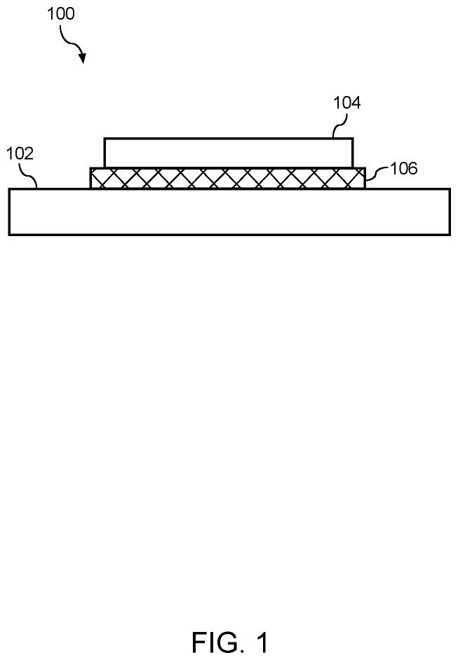

FIG. 1 depicts a cross-sectional view of a portion of an example semiconductor package 100 according to example embodiments of the present disclosure. FIG. 1 is intended to represent structures for identification and description and is not intended to represent the structures to physical scale. The semiconductor package 100 may include a submount 102. The submount 102 may be, for instance, a lead frame or other supporting structure of a wide band gap power semiconductor device, such as a silicon carbide-based semiconductor power module or discrete package. The submount 102 may be, for instance, a copper lead frame and may include other suitable conducting material(s) (e.g., silver plating). In some examples, the submount 102 may be a DBC substrate or a clip structure (e.g., for clip attach).

The semiconductor package 100 may include one or more semiconductor die 104. A single semiconductor die 104 is illustrated in FIG. 1 for purposes of illustration and discussion. Those of ordinary skill in the art, using the disclosures provided herein, will understand that a plurality of semiconductor die 104 (e.g., two or more semiconductor die) may be attached to a submount 102 without deviating from the scope of the present disclosure. The backside of the semiconductor die 104 may be attached to the submount 102 in some examples. However, in other examples, the topside of the semiconductor die 104 may be attached to the submount 102 (e.g., in a flip chip configuration).

The semiconductor die 104 may include one or more devices, such as one or more of a wide variety of power devices available for different applications including, for example, power switching devices and/or power amplifiers. In some examples, the semiconductor die 104 may include one or more transistor devices, such as field effect transistors (FETs) devices, including MOSFETs (metal-oxide semiconductor field-effect transistors), DMOS (double-diffused metal-oxide semiconductor) transistors, HEMTs (high electron mobility transistors), MESFETs (metal-semiconductor field-effect transistors), LDMOS (laterally diffused metal-oxide semiconductor) transistor devices, etc. In some embodiments, the semiconductor die 104 may include one or more diodes (e.g., Schottky diodes, light emitting diodes, etc.).

In some embodiments, the semiconductor die 104 may be fabricated from wide bandgap semiconductor materials (e.g., having a band gap greater than 1.40 cV). For high power, high temperature, and/or high frequency applications, devices formed in wide band gap semiconductor materials such as silicon carbide (e.g., 2.996 eV band gap for alpha silicon carbide at room temperature) and the Group III-nitrides (e.g., 3.36 eV band gap for gallium nitride at room temperature) may provide higher electric field breakdown strengths and higher electron saturation velocities.

Aspects of the present disclosure are discussed with reference to wide bandgap semiconductor devices for purposes of illustration and discussion. Those of ordinary skill in the art, using the disclosures provided herein, will understand that the die-attach materials according to example embodiments of the present disclosure may be used with any semiconductor material or other material without deviating from the scope of the present disclosure.

The semiconductor die 104 may be attached to the submount 102 using a die-attach layer 106. According to example aspects of the present disclosure, the die-attach layer 106 includes gold (Au), tin (Sn), and cobalt (Co). For instance, the die-attach layer 106 is a gold-tin-cobalt (Au—Sn—Co) alloy. The alloy may be a eutectic alloy. A eutectic alloy is a mixture of metals that will melt at a temperature lower than the melting point of any of its individual components.

In some examples, a concentration of cobalt in the die-attach layer 106 may be in a range of about 0.01% by weight to about 0.5% by weight, such as in a range of about 0.01% by weight to about 0.25% by weight. In some examples, a concentration of tin (Sn) in the die-attach layer 106 is in a range of about 10% by weight to about 30% by weight. In some examples, a concentration of gold (Au) in the die-attach layer 106 is in a range of about 65% by weight to about 85% by weight. The die-attach layer may be lead (Pb) free. In some examples, the die-attach layer 106 may include a small amount of other metals (e.g., that diffuse into the die-attach layer during a bonding process), such as nickel (Ni), silver (Ag), palladium (PI), copper (Cu), or aluminum (Al).

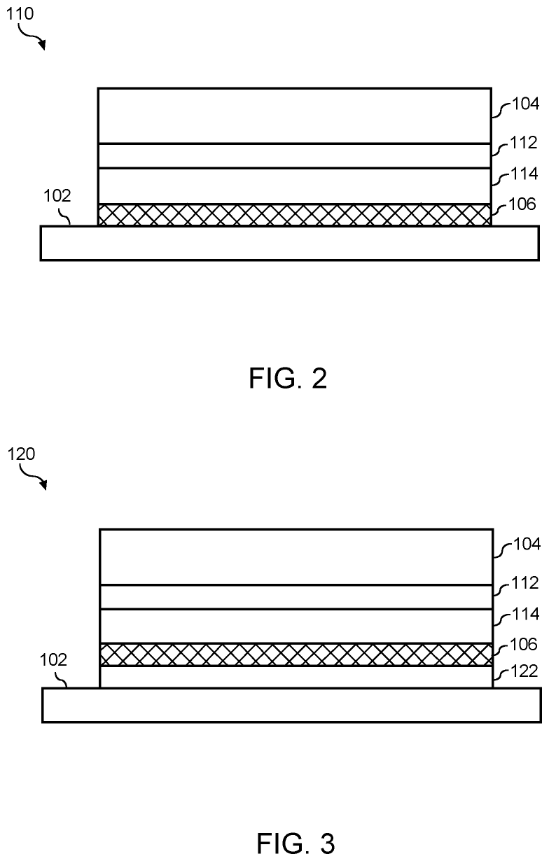

The semiconductor device package according to example embodiments of the present disclosure may include additional layers (e.g., between the semiconductor die and the submount) without deviating from the scope of the present disclosure. For instance, FIG. 2 depicts a portion of an example semiconductor device package 110 according to example embodiments of the present disclosure. FIG. 2 is intended to represent structures for identification and description and is not intended to represent the structures to physical scale. The semiconductor device package 110 is similar to the semiconductor device package 100 shown in FIG. 1. For instance, the semiconductor device package 110 includes a semiconductor die 104 attached to a submount 102 (e.g., a copper lead frame) using a die-attach layer 106. In the example of FIG. 2, the semiconductor device package 110 additionally includes an adhesion layer 112 on the semiconductor die 104 or as part of the semiconductor die 104 (e.g., as part of a metallization layer on the semiconductor die 104). In some embodiments, the adhesion layer 112 may be titanium.

In the example of FIG. 2, the semiconductor device package 110 additionally includes a diffusion barrier layer 114 on the semiconductor die 104 or as part of the semiconductor die 104 (e.g., as part of a metallization layer on the semiconductor die 104). In some embodiments, the diffusion barrier layer 114 may be or include one or more of silver (Ag), nickel (Ni), palladium (Pd), or copper (Cu).

The die-attach layer 106 in the example semiconductor device package 110 of FIG. 2 may include gold (Au), tin (Sn), and cobalt (Co). For instance, the die-attach layer 106 may be a gold-tin-cobalt (Au—Sn—Co) alloy. The alloy may be a eutectic alloy.

In some examples, a concentration of cobalt in the die-attach layer 106 may be in a range of about 0.01% by weight to about 0.5% by weight, such as in a range of about 0.01% by weight to about 0.25% by weight. In some examples, a concentration of tin (Sn) in the die-attach layer 106 is in a range of about 10% by weight to about 30% by weight. In some examples, a concentration of gold (Au) in the die-attach layer 106 is in a range of about 65% by weight to about 85% by weight. The die-attach layer may be lead (Pb) free. In some examples, the die-attach layer 106 may include a small amount of other metals (e.g., that diffuse into the die-attach layer during a bonding process), such as nickel (Ni), silver (Ag), palladium (PI), copper (Cu) or aluminum (Al).

FIG. 3 depicts a portion of an example semiconductor device package 120 according to example embodiments of the present disclosure. FIG. 3 is intended to represent structures for identification and description and is not intended to represent the structures to physical scale. The semiconductor device package 130 is similar to the semiconductor device package 110 shown in FIG. 2. For instance, the semiconductor device package 120 includes a semiconductor die 104 attached to a submount 102 (e.g., a copper lead frame) using a die-attach layer 106. The semiconductor device package 120 includes an adhesion layer 112 and a diffusion barrier layer 114. In the example of FIG. 3, the semiconductor device package 120 additionally includes a protective layer 122 between the die-attach layer 106 and the submount 102. The protective layer 122 may be, for instance, gold or other suitable metal.

The die-attach layer 106 in the example semiconductor device package 120 of FIG. 3 may include gold (Au), tin (Sn), and cobalt (Co). For instance, the die-attach layer 106 may be a gold-tin-cobalt (Au—Sn—Co) alloy. The alloy may be a eutectic alloy.

In some examples, a concentration of cobalt in the die-attach layer 106 may be in a range of about 0.01% by weight to about 0.5% by weight, such as in a range of about 0.01% by weight to about 0.25% by weight. In some examples, a concentration of tin (Sn) in the die-attach layer 106 is in a range of about 10% by weight to about 30% by weight. In some examples, a concentration of gold (Au) in the die-attach layer 106 is in a range of about 65% by weight to about 85% by weight. The die-attach layer may be lead (Pb) free. In some examples, the die-attach layer 106 may include a small amount of other metals (e.g., that diffuse into the die-attach layer during a bonding process), such as nickel (Ni), silver (Ag), palladium (PI), copper (Cu), or aluminum (Al).

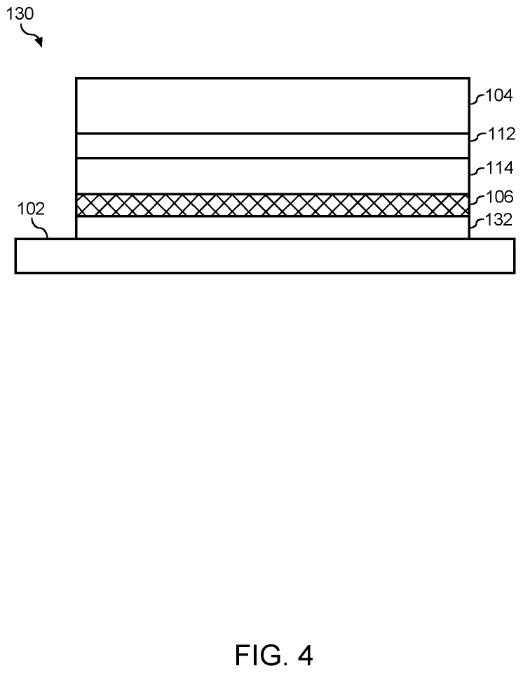

FIG. 4 depicts a portion of an example semiconductor device package 130 according to example embodiments of the present disclosure. FIG. 4 is intended to represent structures for identification and description and is not intended to represent the structures to physical scale. The semiconductor device package 130 is similar to the semiconductor device package 110 shown in FIG. 2. For instance, the semiconductor device package 130 includes a semiconductor die 104 attached to a submount 102 (e.g., a copper lead frame) using a die-attach layer 106. The semiconductor device package 130 includes an adhesion layer 112 and a diffusion barrier layer 114. In the example of FIG. 4, the semiconductor device package 130 is attached to a metal-plated submount 102 that includes a metal-plated layer 132. The metal-plated layer 132 may be, for instance, silver (Ag) or other suitable material(s). For instance, the submount 102 may be a silver-plated copper lead frame.

The die-attach layer 106 in the example semiconductor device package 130 of FIG. 4 may include gold (Au), tin (Sn), and cobalt (Co). For instance, the die-attach layer 106 may be a gold-tin-cobalt (Au—Sn—Co) alloy. The alloy may be a eutectic alloy.

In some examples, a concentration of cobalt in the die-attach layer 106 may be in a range of about 0.01% by weight to about 0.5% by weight, such as in a range of about 0.01% by weight to about 0.25% by weight. In some examples, a concentration of tin (Sn) in the die-attach layer 106 is in a range of about 10% by weight to about 30% by weight. In some examples, a concentration of gold (Au) in the die-attach layer 106 is in a range of about 65% by weight to about 85% by weight. The die-attach layer may be lead (Pb) free. In some examples, the die-attach layer 106 may include a small amount of other metals (e.g., that diffuse into the die-attach layer during a bonding process), such as nickel (Ni), silver (Ag), palladium (PI), copper (Cu), or aluminum (Al).

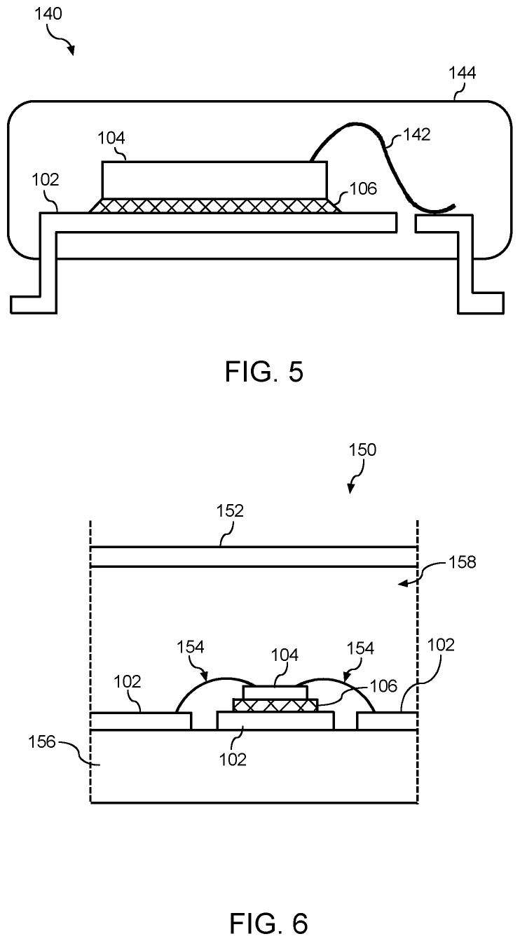

FIG. 5 depicts an example semiconductor package 140 including a semiconductor die 104 attached to a submount 102 according to example embodiments of the present disclosure. As shown, semiconductor package 140 may include a submount 102 (e.g., copper lead frame), semiconductor die 104, and die-attach layer 106 as discussed above with reference to FIGS. 1-4. FIG. 5 depicts one example semiconductor package 140 for purposes of illustration and discussion. Those of ordinary skill in the art, using the disclosures provided herein, will understand that aspects of the present disclosure may be used in a variety of devices and/or applications without deviating from the scope of the present disclosure.

The semiconductor package 140 may be, for instance, a discrete semiconductor package. The semiconductor package 140 may include the conductive submount 102 (e.g., a copper lead frame) on which a semiconductor die 104 containing one or more power devices (e.g., transistors, diodes, etc.) is attached using the die-attach layer 106 described with reference to FIGS. 1-4 according to example embodiments of the present disclosure. The die-attach layer 106 may include gold, tin, and cobalt. The die-attach layer 106 may provide a thermal, mechanical, and electrical connection between the semiconductor die 104 and the conductive submount 102. In some embodiments, the semiconductor die 104 may also be connected to a portion of the conductive submount 102 using wire bonds 142. An encapsulating material 144 (e.g., epoxy mold compound (EMC)) may fill the space around the semiconductor die 104 and the submount 102.

FIG. 6 depicts a cross-sectional view of a portion of a power module 150 according to example embodiments of the present disclosure. FIG. 6 is intended to represent structures for identification and description and is not intended to represent the structures to physical scale. The power module 150 may include a housing 152. The power module 150 may include a conductive submount 102 (e.g., a copper lead frame) on which a semiconductor die 104 containing one or more power devices (e.g., transistors, diodes, etc.) is attached using the die-attach layer 106 described with reference to FIGS. 1-4 according to example embodiments of the present disclosure. The die-attach layer 106 may include gold, tin, and cobalt. The die-attach layer 106 may provide a thermal, mechanical, and electrical connection between the semiconductor die 104 and the conductive submount 102. In some embodiments, the semiconductor die 104 may also be connected to the conductive submount 102 using wire bonds 154. The conductive submount 102 may be mounted on a base layer 156 (e.g., an insulating layer). An inert gel 158 may fill the space between the semiconductor die 104 and the housing 152.

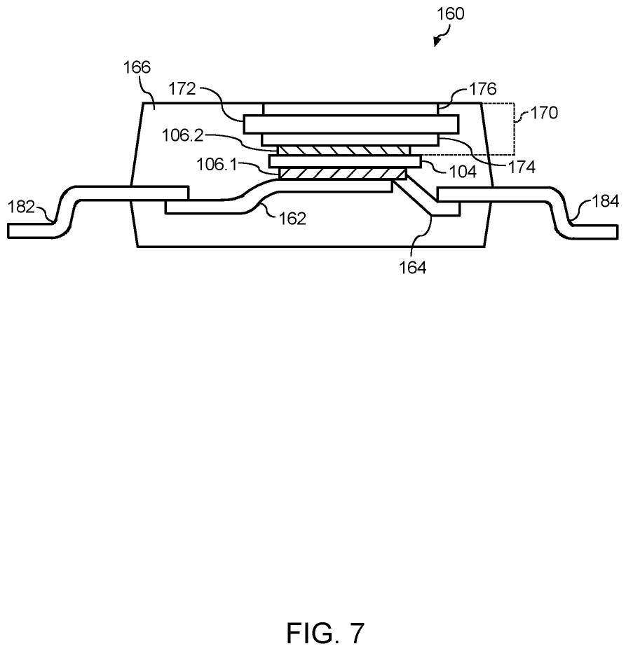

FIG. 7 depicts an example semiconductor package 160 according to example embodiments of the present disclosure. FIG. 7 is intended to represent structures for identification and description and is not intended to represent the structures to physical scale. The semiconductor package 160 may include one or more clip structures, such as clip structure 162 and clip structure 164. The clip structure 162 may be conductively coupled to the lead 182 of the semiconductor package 160.

The clip structure 164 may be conductively coupled to the lead 184 of the semiconductor package 160. The clip structure 164 may be coupled to a DBC submount 170. The DBC submount 170 may include a first conductive layer 174 (e.g., patterned copper layer) and a second conductive layer 176 (e.g., patterned copper layer) separated by an insulating layer 172 (e.g., ceramic layer). The clip structure 164 may be conductively coupled, for instance, to a first conductive layer 174 of the DBC submount 170. The second conductive layer 176 of the DBC submount 170 may provide a topside cooling layer for the semiconductor package 160 in some examples.

According to example aspects of the present disclosure, the semiconductor die 104 (e.g., containing one or more power devices) may be attached to the clip structure 162 using a die-attach layer 106.1 as discussed above with reference to FIGS. 1-4. Similarly, in some examples, the semiconductor die 104 may be attached to the DBC submount 170 (e.g., to the first conductive layer 174) using a die-attach layer 106.2 as discussed above with reference to FIGS. 1-4. An insulating layer 166 (e.g., EMC) may be on or cover the semiconductor die 104, clip structure 162, clip structure 164, DBC submount 170 and other structures of the semiconductor package 160.

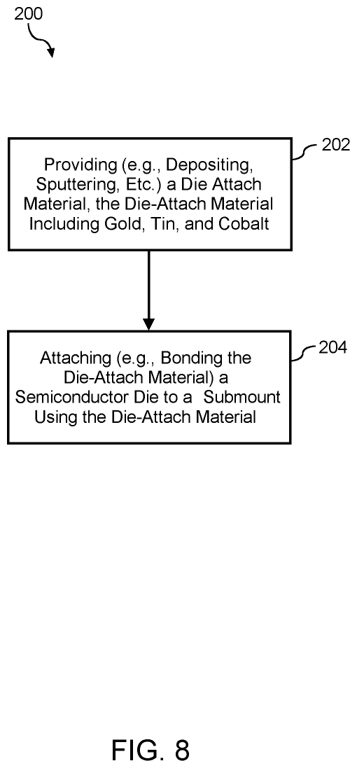

FIG. 8 depicts a flow chart of an example method 200 for fabricating at least a portion of a semiconductor device package according to example embodiments of the present disclosure. FIG. 8 depicts example method steps for purposes of illustration and discussion. Those of ordinary skill in the art, using the disclosures provided herein, will understand that the methods described in the present disclosure may be adapted, modified, include steps not illustrated, omitted, and/or rearranged without deviating from the scope of the present disclosure.

At (202), the method includes providing a die-attach material on a surface, such as a surface of a semiconductor die (e.g., a semiconductor die including a wide bandgap semiconductor) and/or a surface of a submount to which the die-attach material is to be mounted. In some examples, the die-attach material may be provided as a preform or as a paste on a surface of the semiconductor die and/or a surface of the submount. In some examples, the die-attach material may be provided using a deposition process. For instance, in some examples, the die-attach material may be a sputter-defined die-attach material deposited on a surface using a sputter deposition process. In some examples, the die-attach material may be an electrodeposition process defined material deposited on a surface using an electrodeposition process.

According to example aspects of the present disclosure, the die-attach material may include gold, tin, and cobalt. The die attach material may be a gold-tin-cobalt (Au—Sn—Co) alloy. The alloy may be a eutectic alloy. For instance, in some example embodiments, a semiconductor device package may include a submount (e.g., lead frame) and one or more semiconductor die. The semiconductor die may include a wide bandgap semiconductor (e.g., silicon carbide, Group III-nitride, etc.). The semiconductor device package may include a die-attach layer between the submount and the semiconductor die. The die-attach layer includes gold (Au), tin (Sn), and cobalt (Co). In some examples, the die-attach layer is a eutectic alloy (e.g., eutectic Au—Sn—Co alloy).

In some examples, a concentration of cobalt in the die-attach material may be in a range of about 0.01% by weight to about 0.5% by weight, such as in a range of about 0.01% by weight to about 0.25% by weight. In some examples, a concentration of tin (Sn) in the die-attach material is in a range of about 10% by weight to about 30% by weight. In some examples, a concentration of gold (Au) in the die-attach material is in a range of about 65% by weight to about 85% by weight. The die-attach layer may be lead (Pb) free.

At (204), the method may include attaching the semiconductor die to the submount using the die-attach material. In some examples, attaching the semiconductor die to the submount using the die-attach material may include bonding the die-attach material or performing a bonding process on the die-attach material.

In some examples, the bonding process may include heating or annealing the die-attach material to a temperature sufficient to at least partially liquefy the die-attach material, such as a temperature in a range of about 250° C. to about 380° C., such as about 275° C. to about 350° C.

The die-attach material may cool and solidify, attaching the semiconductor die to the submount using the die-attach material. Other suitable bonding processes may be used without deviating from the scope of the present disclosure, such as sintering, reflow, annealing, heating, curing, exposing to light, exposing to ultraviolet light, etc.

Variations and modifications may be made to the example method in FIG. 8 without deviating from the scope of the present disclosure. For instance, the method 200 may include providing a protective layer (e.g., a gold protective layer) on the die-attach material (prior to bonding) as illustrated in FIG. 3

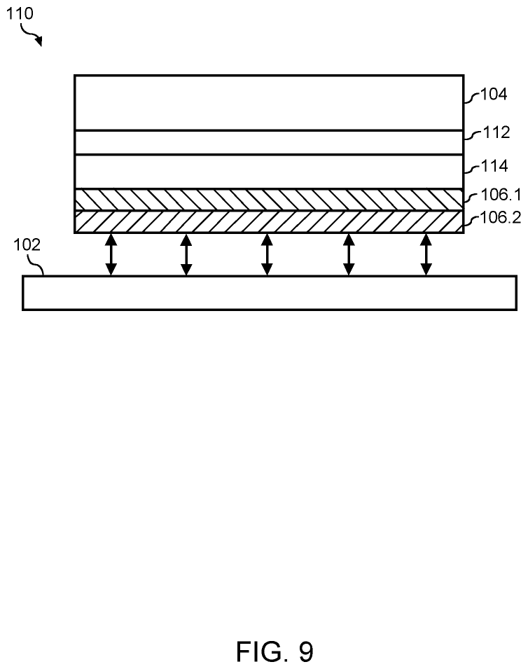

In some examples, as shown in FIG. 9, providing the die-attach material may include providing a first layer 106.1 and providing a second layer 106.2 on the first layer 106.1. The first layer 106.1 may be provided (e.g., using a deposition process, such as a sputter deposition process) on a semiconductor die 104, such as on a diffusion barrier layer 114 on the semiconductor die 104.

The first layer 106.1 may include gold (Au) and cobalt (Co). The second layer 106.2 may include gold (Au) and tin (Sn). Upon bonding (e.g., heating or annealing). The first layer 106.1 and the second layer 106.2 may become a die attach layer 106 including gold (Au), tin (Sn), and cobalt (Co) according to example aspects of the present disclosure. The die-attach layer 106 may be used to attach the semiconductor die 104 to the submount 102 (e.g., copper lead frame).

One example aspect of the present disclosure is directed to a semiconductor device package. The semiconductor device package includes a submount. The semiconductor device package includes a semiconductor die comprising a wide bandgap semiconductor. The semiconductor device package includes a die-attach layer between the submount and the semiconductor die. The die-attach layer comprises gold (Au), tin (Sn), and cobalt (Co).

In some examples, a concentration of cobalt in the die-attach layer is in a range of about 0.01% by weight to about 0.5% by weight.

In some examples, a concentration of cobalt in the die-attach layer is in a range of about 0.01% by weight to about 0.25% by weight.

In some examples, the die-attach layer comprises a eutectic alloy.

In some examples, the semiconductor device package comprises a protective layer on the die-attach layer.

In some examples, the protective layer comprises gold.

In some examples, the die-attach layer further comprises nickel (Ni), silver (Ag), copper (Cu), or aluminum (Al).

In some examples, the semiconductor device package comprises an adhesion layer.

In some examples, the adhesion layer comprises titanium.

In some examples, the semiconductor device package comprises a diffusion barrier layer.

In some examples, the diffusion barrier layer comprises one or more of silver (Ag), nickel (Ni), palladium (Pd), or copper (Cu).

In some examples, a concentration of tin (Sn) in the die-attach layer is in a range of about 10% by weight to about 30% by weight.

In some examples, a concentration of gold (Au) in the die-attach layer is in a range of about 65% by weight to about 85% by weight.

In some examples, the die-attach layer is lead (Pb) free.

In some examples, the submount comprises copper (Cu).

In some examples, the submount comprises silver-plated copper (Cu).

In some examples, the submount comprises a lead frame, a clip structure, or a direct bonded copper (DBC) submount.

In some examples, the wide bandgap semiconductor comprises silicon carbide.

In some examples, the wide bandgap semiconductor comprises a Group III-nitride.

In some examples, the semiconductor device package is a discrete power semiconductor package.

In some examples, the semiconductor device package is a power module.

Another example aspect of the present disclosure is directed to an attach material for attaching a wide bandgap semiconductor device to a submount. The attach material comprises a eutectic alloy. The eutectic alloy comprises gold (Au), tin (Sn), and cobalt (Co). A concentration of cobalt in the eutectic alloy is in a range of about 0.01% by weight to about 0.5% by weight.

In some examples, a concentration of cobalt in the eutectic alloy is in a range of about 0.01% by weight to about 0.25% by weight.

In some examples, a concentration of tin (Sn) in the eutectic alloy is in a range of about 10% by weight to about 30% by weight.

In some examples, a concentration of gold (Au) in the eutectic alloy is in a range of about 65% by weight to about 85% by weight.

In some examples, the attach material is lead (Pb) free.

In some examples, the attach material is a preform.

In some examples, the attach material is a paste.

In some examples, the attach material is a sputter-defined attach material.

In some examples, the attach material is an electrodeposition process defined attach material.

Another example aspect of the present disclosure is directed to a method for fabricating a semiconductor device package. The method includes providing a die-attach material. The die-attach material comprises gold (Au), tin (Sn), and cobalt (Co). A concentration of cobalt (Co) in the die-attach material is in a range of about 0.01% by weight to about 0.5% by weight. The method includes attaching a semiconductor die to a submount with the die-attach material.

In some examples, providing a die-attach material comprises providing the die-attach material on the semiconductor die, the semiconductor die comprising a wide bandgap semiconductor.

In some examples, providing a die-attach material comprises providing the die-attach material on a submount.

In some examples, attaching the semiconductor die to a submount comprises bonding the die-attach material.

In some examples, providing the die-attach material comprises depositing the die-attach material using a sputter deposition process.

In some examples, providing the die-attach material comprises depositing the die-attach using an electrodeposition process.

In some examples, the die-attach material is a paste.

In some examples, the die-attach material is a preform.

In some examples, providing the die-attach material comprises providing a first layer and providing a second layer on the first layer, wherein the first layer comprises gold (Au) and cobalt (Ci) and the second layer comprises gold (Au) and tin (Sn).

In some examples, the semiconductor device package comprises an adhesion layer.

In some examples, the adhesion layer comprises titanium.

In some examples, the semiconductor device package comprises a diffusion barrier layer.

In some examples, the diffusion barrier layer comprises one or more of silver (Ag), nickel (Ni), palladium (Pd), or copper (Cu).

In some examples, the method comprises providing a protective layer on the die-attach material.

In some examples, the protective layer comprises gold.

In some examples, a concentration of cobalt in the die-attach material is in a range of about 0.01% by weight to about 0.25% by weight.

In some examples, a concentration of tin (Sn) in the die-attach material is in a range of about 10% by weight to about 30% by weight.

In some examples, a concentration of gold (Au) in the die-attach material is in a range of about 65% by weight to about 85% by weight.

In some examples, the die-attach material is lead (Pb) free.

In some examples, the submount comprises copper (Cu).

In some examples, the submount comprises a silver-plated copper (Cu).

In some examples, the submount comprises a lead frame, a clip structure, or a direct bonded copper (DBC) submount.

In some examples, the wide bandgap semiconductor comprises silicon carbide.

In some examples, the wide bandgap semiconductor comprises a Group III-nitride.

While the present subject matter has been described in detail with respect to specific example embodiments thereof, it will be appreciated that those skilled in the art, upon attaining an understanding of the foregoing may readily produce alterations to, variations of, and equivalents to such embodiments. Accordingly, the scope of the present disclosure is by way of example rather than by way of limitation, and the subject disclosure does not preclude inclusion of such modifications, variations and/or additions to the present subject matter as would be readily apparent to one of ordinary skill in the art.

1. A semiconductor device package, comprising:
a submount;
a semiconductor die comprising a wide bandgap semiconductor;
a die-attach layer between the submount and the semiconductor die; and
wherein the die-attach layer comprises gold (Au), tin (Sn), and cobalt (Co).

2. The semiconductor device package of claim 1, wherein a concentration of cobalt in the die-attach layer is in a range of about 0.01% by weight to about 0.5% by weight.

3. The semiconductor device package of claim 1, wherein a concentration of cobalt in the die-attach layer is in a range of about 0.01% by weight to about 0.25% by weight.

4. The semiconductor device package of claim 1, wherein the die-attach layer comprises a eutectic alloy.

5. The semiconductor device package of claim 1, wherein the semiconductor device package comprises a protective layer on the die-attach layer.

6. The semiconductor device package of claim 5, wherein the protective layer comprises gold.

7. The semiconductor device package of claim 1, wherein the die-attach layer further comprises nickel (Ni), silver (Ag), copper (Cu), or aluminum (Al).

8. The semiconductor device package of claim 1, wherein the semiconductor device package comprises an adhesion layer.

9. (canceled)

10. The semiconductor device package of claim 8, further comprising a diffusion barrier layer.

11. The semiconductor device package of claim 10, wherein the diffusion barrier layer comprises one or more of silver (Ag), nickel (Ni), palladium (Pd), or copper (Cu).

12. The semiconductor device package of claim 1, wherein a concentration of tin (Sn) in the die-attach layer is in a range of about 10% by weight to about 30% by weight.

13. The semiconductor device package of claim 1, wherein a concentration of gold (Au) in the die-attach layer is in a range of about 65% by weight to about 85% by weight.

14. The semiconductor device package of claim 1, wherein the die-attach layer is lead (Pb) free.

15. The semiconductor device package of claim 1, wherein the submount comprises copper (Cu).

16. The semiconductor device package of claim 1, wherein the submount comprises silver-plated copper (Cu).

17. The semiconductor device package of claim 1, wherein the submount comprises a lead frame, a clip structure, or a direct bonded copper (DBC) submount.

18. The semiconductor device package of claim 1, wherein the wide bandgap semiconductor comprises silicon carbide or a Group III nitride.

19. (canceled)

20. The semiconductor device package of claim 1, wherein the semiconductor device package is a discrete power semiconductor package or a power module.

21. (canceled)

22. An attach material for attaching a wide bandgap semiconductor device to a submount, the attach material comprising a eutectic alloy, the eutectic alloy comprising gold (Au), tin (Sn), and cobalt (Co), wherein a concentration of cobalt in the eutectic alloy is in a range of about 0.01% by weight to about 0.5% by weight.

23.-30. (canceled)

31. A method for fabricating a semiconductor device package, comprising:
providing a die-attach material, the die-attach material comprising gold (Au), tin (Sn), and cobalt (Co), wherein a concentration of cobalt (Co) in the die-attach material is in a range of about 0.01% by weight to about 0.5% by weight; and
attaching a semiconductor die to a submount with the die-attach material.

32.-54. (canceled)
